(19) United States
(12) Patent Application Publication
(10) Pub. No.: US 2025/0094673 A1
(43) Pub. Date: Mar. 20, 2025

(54) REAL-TIME DYNAMIC PREDICTION SYSTEM AND METHOD OF THREE-DIMENSIONAL SHAPE OF HIGH-PRESSURE JET GROUTING PILE

(71) Applicants: CHINA RAILWAY FOURTH ENGINEERING GROUP CO., LTD, Hefei, Anhui (CN); CHINA RAILWAY FOURTH ENGINEERING GROUP CONSTRUCTION ENGINEERING CO., LTD, Hefei, Anhui (CN); HEFEI POLYTECHNIC UNIVERSITY, Hefei, Anhui (CN)

(72) Inventors: Ruixue CAO, Hefei, Anhui (CN); Leilei GUO, Hefei, Anhui (CN); Zaixing XU, Hefei, Anhui (CN); Jinhua HE, Hefei, Anhui (CN); Yixian WANG, Hefei, Anhui (CN); Bao XU, Hefei, Anhui (CN); Panpan GUO, Hefei, Anhui (CN); Yuan GAO, Hefei, Anhui (CN); Yongli LIU, Hefei, Anhui (CN); Jun NIE, Hefei, Anhui (CN); Feifei WU, Hefei, Anhui (CN); Ruowang YANG, Hefei, Anhui (CN); Lianbiao HOU, Hefei, Anhui (CN); Dongfang YAO, Hefei, Anhui (CN)

(21) Appl. No.: 18/262,714

(22) PCT Filed: Jun. 6, 2023
(86) PCT No.: PCT/CN2023/098573

§ 371 Date: Jul. 24, 2023

(51) Int. Cl. G06F 30/27; G06F 30/13

(52) U.S. Cl. CPC G06F 30/27; G06F 30/13

(57) ABSTRACT

The present disclosure provides a real-time dynamic prediction system and method of a three-dimensional shape of a high-pressure jet grouting pile. The method includes: obtaining a training data set; a model construction module constructs a high-pressure jet grouting pile diameter prediction model based on a bidirectional recurrent neural network (BRNN) and a gated recurrent unit (GRU); a model training module trains the high-pressure jet grouting pile diameter prediction model based on the training data set; a prediction module predicts based on the trained high-pressure jet grouting pile diameter prediction model, to obtain diameter prediction information in a construction process of a construction project; and a high-pressure jet grouting pile diameter output module determines whether the diameter prediction information matches a diameter mode; if the diameter prediction information matches the diameter mode, the high-pressure jet grouting pile diameter output module outputs the diameter prediction information.

This application is a national stage application of International Patent Application No. PCT/CN2023/098573, filed on Jun. 6, 2023.

### TECHNICAL FIELD

The present disclosure relates to the technical field of constructional engineering, and in particular, to a real-time dynamic prediction system and method of a three-dimensional shape of a high-pressure jet grouting pile.

### BACKGROUND

With the continuous development of infrastructure, high-pressure jet grouting has become a popular soil stabilization technology that is widely used in the construction industry to deal with challenges of various geotechnical projects. A high-pressure jet grouting method is to form continuous overlapping reinforced concrete by spraying cement slurry into a soil layer and mixing with a soil body through a high-pressure rotating nozzle. This method has advantages of a small occupied area for construction, low vibration, and low noise. However, this method pollutes the environment, has high costs, and is not suitable for special soil that cannot solidify the sprayed slurry. Therefore, it is necessary to accurately predict parameters of a high-pressure jet grouting pile, to ensure safety and reliability in a construction process.

Most of researches in a conventional technology do not consider influential effect of complex strata on parameters of the high-pressure jet grouting pile. If a mean diameter of high-pressure jet grouting piles is used as a key indicator, it is difficult to dynamically monitor a diameter of the pile in real time. Therefore, it is necessary to design a real-time dynamic prediction system and method of a three-dimensional shape of the high-pressure jet grouting pile.

### SUMMARY

An objective of the present disclosure is to provide a real-time dynamic prediction system and method of a three-dimensional shape of a high-pressure jet grouting pile, to realize real-time dynamic evaluation of a diameter of the high-pressure jet grouting pile, and feed back and correct data input by a prediction model, and effectively improve prediction accuracy.

To achieve the above objective, the present disclosure provides the following technical solutions:

A real-time dynamic prediction system of a three-dimensional shape of a high-pressure jet grouting pile includes a model construction module, a model training module, a prediction module, and a high-pressure jet grouting pile diameter output module. The model construction module is connected with the model training module, the model training module is connected with the prediction module, and the prediction module is connected with the high-pressure jet grouting pile diameter output module.

The model construction module is configured to construct a high-pressure jet grouting pile diameter prediction model based on a bidirectional recurrent neural network (BRNN) and a gated recurrent unit (GRU).

The model training module is configured to: obtain a training data set, and train the high-pressure jet grouting pile diameter prediction model based on the training data set.

The prediction module is configured to perform prediction based on the trained high-pressure jet grouting pile diameter prediction model, to obtain diameter prediction information in a construction process of a construction project.

The high-pressure jet grouting pile diameter output module is configured to: determine whether the obtained diameter prediction information matches a diameter mode. If the obtained diameter prediction information does not match the diameter mode, high-pressure jet grouting pile diameter output module adjusts an operation parameter of the high-pressure jet grouting pile diameter prediction model and perform prediction again. If the obtained diameter prediction information matches the diameter mode, the high-pressure jet grouting pile diameter output module outputs the diameter prediction information.

The present disclosure further provides a real-time dynamic prediction method of a three-dimensional shape of a high-pressure jet grouting pile, applied to the foregoing real-time dynamic prediction system of a three-dimensional shape of a high-pressure jet grouting pile, including the following steps.

Step 1: Obtain a training data set.

Step 2: A model construction module constructs a high-pressure jet grouting pile diameter prediction model based on a bidirectional recurrent neural network (BRNN) and a gated recurrent unit (GRU).

Step 3: A model training module trains the high-pressure jet grouting pile diameter prediction model based on the training data set.

Step 4: A prediction module predicts based on the trained high-pressure jet grouting pile diameter prediction model, to obtain diameter prediction information in a construction process of a construction project.

Step 5: A high-pressure jet grouting pile diameter output module determines whether the diameter prediction information matches a diameter mode. If the diameter prediction information matches the diameter mode, the high-pressure jet grouting pile diameter output module outputs the diameter prediction information. If the diameter prediction information does not match the diameter mode, the high-pressure jet grouting pile diameter output module adjusts an operation parameter of the high-pressure jet grouting pile diameter prediction model, perform prediction again until the diameter prediction information matches the diameter mode, and outputs the diameter prediction information.

Optionally, in the step 1, the obtaining a training data set specifically includes:
obtaining parameters of a soil layer based on relevant soil data collected through site survey; obtaining a jetting parameter and a diameter of the high-pressure jet grouting pile based on a high-pressure jet grouting pile test, namely, parameters of a pile test; and constructing the training data set based on the parameters of the soil layer and the parameters of the pile test.

Optionally, in the step 2, a model construction module constructs the high-pressure jet grouting pile diameter prediction model based on a BRNN and a GRU specifically includes:

The model construction module constructs a BRNN and GRU fusion model based on the BRNN and the GRU, namely, the high-pressure jet grouting pile diameter prediction model. The BRNN and GRU fusion model is configured to connect two opposite hidden layers to a same output layer, and the output layer simultaneously receives information forward and backward based on generative deep learning.

Optionally, in the step 3, the model training module trains the high-pressure jet grouting pile diameter prediction model based on the training data set specifically includes the following steps.

Step 301: The model training module obtains the training data set, and screens an effective data parameter from the parameters of the soil layer and the parameters of the pile test, to enable the BRNN in the high-pressure jet grouting pile diameter prediction model to include 300 hidden layers.

Step 302: Set an input variable, including a jetting parameter, increment time, a soil depth, and porosity, where the jetting parameter includes a revolution Rot per lifting step, a flow rate Q, a number N of nozzles, a diameter d of the nozzle, injection time Dt per lifting step, a mean rotational speed w, an injected grout volume Vj′, and a lifting speed v, and an output is diameter of a column with a specific depth. For the parameters of the soil layer, all diameter values collected from first six columns are arranged as a soil layer training vector sequence. For the parameters of the pile test, all diameter values collected from last six columns are arranged as a test training vector sequence.

Step 303: Input the soil layer training vector sequence and the test training vector sequence into a high-pressure jet grouting pile diameter prediction model at corresponding time, and train the high-pressure jet grouting pile diameter prediction model. In this case, the BRNN and the GRU in the high-pressure jet grouting pile diameter prediction model are trained for 300 epochs.

Step 304: In the training process, if there is an error between an output training result and an output of a preset labeled structure, transmit the error to a recurrent neural network of the high-pressure jet grouting pile diameter prediction model step by step through a backward algorithm; the high-pressure jet grouting pile diameter prediction model automatically adjusts weight parameters of each neuron; and stop training after a success rate of the training result reaches a preset threshold, to complete the training of the high-pressure jet grouting pile diameter prediction model.

According to specific embodiments provided by the prevent disclosure, the prevent disclosure discloses the following technical effects: According to the real-time dynamic prediction system and method of a three-dimensional shape of a high-pressure jet grouting pile provided by the prevent disclosure, method includes: obtaining a training data set; a model construction module constructs a high-pressure jet grouting pile diameter prediction model based on a BRNN and a GRU; a model training module trains the high-pressure jet grouting pile diameter prediction model based on the training data set; a prediction module predicts based on the trained high-pressure jet grouting pile diameter prediction model, to obtain diameter prediction information in a construction process of a construction project; and a high-pressure jet grouting pile diameter output module determines whether the diameter prediction information matches a diameter mode; if the diameter prediction information matches the diameter mode, the high-pressure jet grouting pile diameter output module outputs the diameter prediction information; and if the diameter prediction information does not match the diameter mode, the high-pressure jet grouting pile diameter output module adjusts an operation parameter of the high-pressure jet grouting pile diameter prediction model, perform prediction again until the diameter prediction information matches the diameter mode, and outputs the diameter prediction information. The system and the method adopt bidirectional recurrent prediction, so that training efficiency is improved to a great extent, the input data of the prediction model is fed back and corrected, change of actual data of the jet grouting pile is accurately reflected with time, effectiveness of model construction is effectively reduced in a high-pressure jet grouting process, suggestions to improve a current high-pressure jet grouting pile design are conveniently put forward based on analysis and prediction results, and potential risks in engineering practice are reduced.

### BRIEF DESCRIPTION OF THE DRAWINGS

To describe the technical solutions in embodiments of the present disclosure or in the prior art more clearly, the accompanying drawings required in the embodiments are briefly described below. Apparently, the accompanying drawings in the following description show merely some embodiments of the present disclosure, and other drawings can be derived from these accompanying drawings by those of ordinary skill in the art without creative efforts.

FIG. 1 is a schematic diagram of a structure of a real-time dynamic prediction system of a three-dimensional shape of a high-pressure jet grouting pile according to an embodiment of the present disclosure;

FIG. 2 is a first schematic flowchart of a real-time dynamic prediction method of a three-dimensional shape of a high-pressure jet grouting pile according to an embodiment of the present disclosure;

FIG. 3 is a second schematic flowchart of a real-time dynamic prediction method of a three-dimensional shape of a high-pressure jet grouting pile according to an embodiment of the present disclosure; and

FIG. 4 is a schematic diagram of a BRNN and GRU fusion model.

### DETAILED DESCRIPTION OF THE EMBODIMENTS

An objective of the present disclosure is to provide a real-time dynamic prediction system and method of a three-dimensional shape of a high-pressure jet grouting pile, to realize real-time dynamic evaluation of a diameter of the high-pressure jet grouting pile, feed back and correct data input by a prediction model, and effectively improve prediction accuracy.

To make the above objectives, features, and advantages of the present disclosure clearer and more comprehensible, the present disclosure will be further described in detail below with reference to the accompanying drawings and the specific examples.

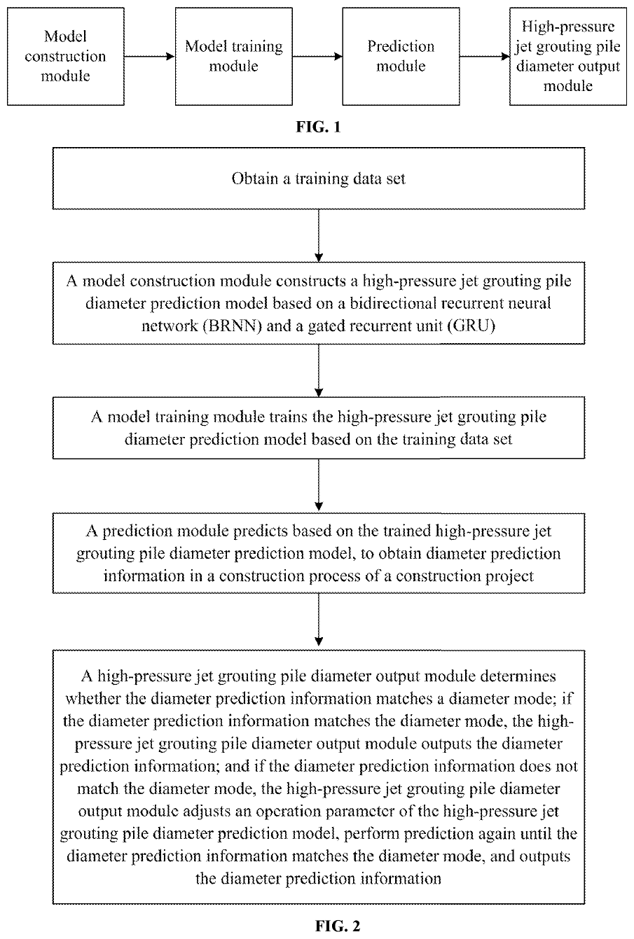

As shown in FIG. 1, a real-time dynamic prediction system of a three-dimensional shape of a high-pressure jet grouting pile provided by an embodiment of the present disclosure includes a model construction module, a model training module, a prediction module, and a high-pressure jet grouting pile diameter output module. The model construction module is connected with the model training module, the model training module is connected with the prediction module, and the prediction module is connected with the high-pressure jet grouting pile diameter output module.

The model construction module is configured to construct a high-pressure jet grouting pile diameter prediction model based on a BRNN and a GRU.

The model training module is configured to: obtain a training data set, and train the high-pressure jet grouting pile diameter prediction model based on the training data set.

The prediction module is configured to perform prediction based on the trained high-pressure jet grouting pile diameter prediction model, to obtain diameter prediction information in a construction process of a construction project.

The high-pressure jet grouting pile diameter output module is configured to: determine whether the obtained diameter prediction information matches a diameter mode. If the obtained diameter prediction information does not match the diameter mode, the high-pressure jet grouting pile diameter output module adjusts an operation parameter of the high-pressure jet grouting pile diameter prediction model and perform prediction again. If the obtained diameter prediction information matches the diameter mode, the high-pressure jet grouting pile diameter output module outputs the diameter prediction information.

According to the present disclosure, a diameter of the high-pressure jet grouting pile is predicted by using the BRNN and the GRU. The algorithm can execute a learning process from two directions, and combine relevant parameters of the high-pressure jet grouting pile with the BRNN and GRU fusion model, to save diameter information of the high-pressure jet grouting pile measured previously and in future at any time point, so that reliability and globality of a data result are higher.

According to the present disclosure, the high-pressure jet grouting pile is predicted based on both a preceding database and a following database. In addition, a fused machine learning model can adjust an unmatched parameter structure in a timely manner, to learn advanced features from data. This can be regarded as a unique progress of deep learning in comparison with a conventional machine learning technology. Compared with the conventional machine learning, another outstanding advantage of the deep learning model is that the deep learning model can deal with problems of time series. In other words, a problem of a feedforward network that cannot deal with concept of time sequence or a problem of a recurrent neural network that has gradient vanishing can be resolved based on previous observation results.

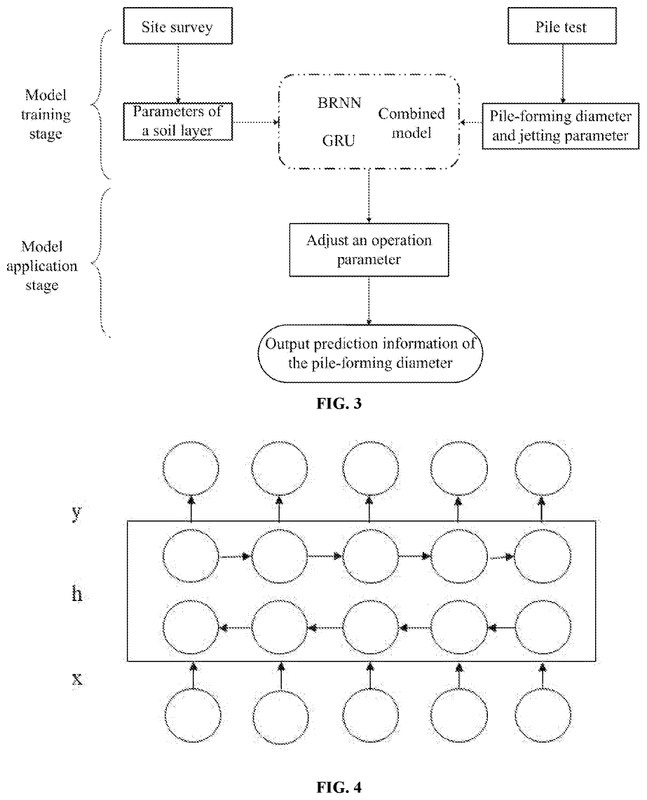

As shown in FIG. 2 and FIG. 3, the present disclosure further provides a real-time dynamic prediction method of a three-dimensional shape of a high-pressure jet grouting pile, applied to the foregoing real-time dynamic prediction system of a three-dimensional shape of a high-pressure jet grouting pile, including the following steps.

Step 1: Obtain a training data set.

Step 2: A model construction module constructs a high-pressure jet grouting pile diameter prediction model based on a BRNN and a GRU.

Step 3: A model training module trains the high-pressure jet grouting pile diameter prediction model based on the training data set.

Step 4: A prediction module predicts based on the trained high-pressure jet grouting pile diameter prediction model, to obtain diameter prediction information in a construction process of a construction project.

Step 5: A high-pressure jet grouting pile diameter output module determines whether the diameter prediction information matches a diameter mode. If the diameter prediction information matches the diameter mode, the high-pressure jet grouting pile diameter output module outputs the diameter prediction information. If the diameter prediction information does not match the diameter mode, the high-pressure jet grouting pile diameter output module adjusts an operation parameter of the high-pressure jet grouting pile diameter prediction model, perform prediction again until the diameter prediction information matches the diameter mode, and outputs the diameter prediction information.

In the step 1, the obtaining a training data set specifically includes:
obtaining parameters of a soil layer based on relevant soil data collected through site survey; obtaining a jetting parameter and a diameter of the high-pressure jet grouting pile based on a high-pressure jet grouting pile test, namely, parameters of a pile test; and constructing the training data set based on the parameters of the soil layer and the parameters of the pile test.

In the step 2, a model construction module constructs the high-pressure jet grouting pile diameter prediction model based on a BRNN and a GRU specifically includes:

The model construction module constructs a BRNN and GRU fusion model based on the BRNN and the GRU, namely, the high-pressure jet grouting pile diameter prediction model. The BRNN and GRU fusion model is configured to connect two opposite hidden layers to a same output layer, and the output layer simultaneously receives information forward and backward based on generative deep learning.

FIG. 4 shows the BRNN and GRU fusion model.

The BRNN and GRU fusion model connects the two opposite hidden layers to the same output layer, and the output layer simultaneously receives the information forward and backward based on the generative deep learning. A standard recurrent neural network has limitations, namely, future data cannot be expressed in a current state. The BRNN and GRU fusion model can make up for disadvantages of the standard recurrent neural network, and does not need to fix the input data. In addition, future input data can be expressed in the current state.

A working principle of the BRNN and GRU fusion model is that neurons of a regular RNN are divided into two directions, one is a positive time direction (a positive state) and the other is a negative time direction (a reverse state). Outputs of the two states are not connected to inputs of an opposite state. Through the two time directions, past and future information of a current time frame may be used as input information. By considering that a current output is not only related to a previous sequence element, but also related to a subsequent sequence element. In addition, the fusion model has a fast convergence speed. This accelerates a test process and realizes fast iteration, so that there is a good practical significance in prediction of the pile test.

When in use, the soil layer parameter sequence that is to be processed and that is in the parameters of the soil layer is transformed into a corresponding vector data sequence through the BRNN and GRU fusion model, and the vector data sequence is input into the BRNN and GRU fusion model in the forward direction and the reverse direction in the model.

The corresponding vector data sequence that is transformed by the BRNN and GRU fusion model and that in the parameters of the pile test is input into corresponding vector data sequences, and the vector data sequences are input into a BRNN and GRU fusion model at a corresponding moment in the forward direction and the backward direction of the vector data sequence.

The BRNN and GRU fusion model outputs the vector sequence to be processed, and the high-pressure jet grouting pile diameter output module outputs the diameter of the high-pressure jet grouting pile based on the BRNN and GRU fusion model.

According to the system of the present disclosure, the structure is complete, the parameters of the soil layer and the parameters of the pile test are automatically converted into corresponding sequences that can be recognized by a computer, to obtain the diameter of the high-pressure jet grouting pile. Comprehensively, a capability of the BRNN and GRU fusion model to dynamically predict the diameter of the high-pressure jet grouting pile is investigated through the two data sorting solutions.

Further, the parameters of the soil layer are transmitted to the hidden layer of the BRNN and GRU fusion model, the hidden layer is a two-dimensional matrix, each vector of the matrix corresponds to a soil parameter in the parameters of the soil layer, a corresponding relationship between the parameter of the soil layer and a vector is set when the hidden layer is constructed, a vector data sequence is formed after the parameter of the soil layer is processed by the hidden layer, and the vector data sequence is input into the BRNN and GRU fusion model.

The parameters of the pile test are transmitted to the hidden layer of the BRNN and GRU fusion model, the hidden layer is a two-dimensional matrix, each vector of the matrix corresponds to the direction and the jet grouting parameter in the parameters of the pile test, a corresponding relationship between the parameter of the pile test and a vector is set when the hidden layer is constructed, a vector data sequence is formed after the parameter of the pile test is processed by the hidden layer, and the vector data sequence is input into the BRNN and GRU fusion model.

The two vector data sequences are processed by the BRNN and GRU fusion model, and then converted into corresponding diameter parameter of the high-pressure jet grouting pile. This overcomes inaccuracy of prediction of a unidirectional data parameter.

Specifically, a neural network algorithm formula in BRNN module is:

$${\vec{h}}_{t} = f ( \vec{W} {x}_{t} + \vec{V} {\vec{h}}_{h - 1} + \vec{b} ) \\ {\overleftarrow{h}}_{t} = f ( \overleftarrow{W} {x}_{t} + \overleftarrow{V} {\overleftarrow{h}}_{h - 1} + \overleftarrow{b} ) \\ {y}_{t} = g ( U [ {\vec{h}}_{t} ⊕ {\overleftarrow{h}}_{t} ] + c )$$

f and g are excitation functions, and the common excitation functions include a logistic function and a hyperbolic tangent function; x={x₁, x₂, . . . , xₙ}, n represents an expansion length of the BRANN; and ⊕ represents matrix splicing. For a time step t, a loop unit of the RNN h^{(t)}=f(s^{(t-1)},x^{(t)},θ): h represents a system state of the BRNN. From the viewpoint of a dynamical system, the system state describes a change of all points in a given space with the time step.

It should be noted that the BRNN module includes two RNN hidden layers, namely, a forward RNN hidden layer and a reverse RNN hidden layer. States of the two hidden layers are combined to obtain an output y.

Specifically, a neural network algorithm formula in the GRU module is:

$${z}_{t} = σ ( {W}_{z} {x}_{t} + {U}_{z} {h}_{t - 1} + {b}_{z} ) \\ {r}_{t} = σ ( {W}_{r} {x}_{t} + {U}_{r} {h}_{t - 1} + {b}_{r} ) \\ {\vec{h}}_{t} = tanh ( {W}_{h} {x}_{t} + {U}_{h} ( {r}_{t} ▯ {h}_{t - 1} ) + {b}_{h} ) \\ {h}_{t} = {z}_{t} ▯ {h}_{t - 1} + ( 1 - {z}_{t} ) ▯ {\vec{h}}_{t}$$

When zₜ=0, a current state hₜ and a previous state hₜ₋₁ are nonlinear; and when zₜ=1, hₜ and hₜ₋₁ are linear.

In the step 3, the model training module trains the high-pressure jet grouting pile diameter prediction model based on the training data set specifically includes the following steps.

Step 301: The model training module obtains the training data set, and screens an effective data parameter from the parameters of the soil layer and the parameters of the pile test, to enable the BRNN in the high-pressure jet grouting pile diameter prediction model to include 300 hidden layers.

Step 302: Set an input variable, including a jetting parameter, increment time, a soil depth, and porosity, where the jetting parameter includes a revolution Rot per lifting step, a flow rate Q, a number N of nozzles, a diameter d of the nozzle, injection time Dt per lifting step, a mean rotational speed w, an injected grout volume Vi′, and a lifting speed v, and an output is diameter of a column with a specific depth. For the parameters of the soil layer, all diameter values collected from first six columns are arranged as a soil layer training vector sequence. For the parameters of the pile test, all diameter values collected from last six columns are arranged as a test training vector sequence.

Step 303: Input the soil layer training vector sequence and the test training vector sequence into a high-pressure jet grouting pile diameter prediction model at corresponding time, and train the high-pressure jet grouting pile diameter prediction model. In this case, the BRNN and the GRU in the high-pressure jet grouting pile diameter prediction model are trained for 300 epochs, where the corresponding input includes not only the parameters of the soil layer and the parameters of the pile test, but also vector data in the hidden layer.

Step 304: In the training process, if there is an error between an output training result and an output of a preset labeled structure, transmit the error to a recurrent neural network of the high-pressure jet grouting pile diameter prediction model step by step through a backward algorithm; the high-pressure jet grouting pile diameter prediction model automatically adjusts weight parameters of each neuron; and stop training after a success rate of the training result reaches a preset threshold, to complete the training of the high-pressure jet grouting pile diameter prediction model, where an initial learning rate is set to 0.01, and a gradient threshold value is set to be equal to 1, to prevent gradient explosion.

According to the system of the present disclosure, operation data is transmitted layer by layer in the BRNN and GRU fusion model through the forward algorithm, and prediction data of identification of the diameter is obtained in the output layer. When the prediction result has deviation from a labeling result of a training sample, each weight in the neural network is adjusted through a classical error back propagation algorithm in the neural network. An error can be distributed step by step to all neurons in each layer through the error back propagation algorithm, to obtain an error signal of neurons in each layer, and then correct a weight of each neuron. A training process of the neural network is a process in which operation data is transmitted layer by layer through a forward algorithm and the weight of each neuron is gradually modified through a backward algorithm. The foregoing process is repeated, and the training is stopped until a success rate of a prediction result reaches a preset threshold. In this case, it can be considered that training of the BRNN and GRU fusion model is completed.

The present disclosure further provides an electric device, including a memory, a processor, and a computer program stored in the memory and executable on the processor, where the computer program is executed by the processor to implement the above method.

Optimally, the electronic device includes a memory, a processor, and a computer program stored on the memory and executable on the processor, where the computer program executes the foregoing steps, and the processor executes the computer program to implement direction prediction.

According to the real-time dynamic prediction system and method of a three-dimensional shape of a high-pressure jet grouting pile provided by the prevent disclosure. The method includes: obtaining a training data set; a model construction module constructs a high-pressure jet grouting pile diameter prediction model based on the BRNN and the GRU; a model training module trains the high-pressure jet grouting pile diameter prediction model based on the training data set; a prediction module predicts based on the trained high-pressure jet grouting pile diameter prediction model, to obtain diameter prediction information in a construction process of a construction project; and a high-pressure jet grouting pile diameter output module determines whether the diameter prediction information matches a diameter mode; if the diameter prediction information matches the diameter mode, the high-pressure jet grouting pile diameter output module outputs the diameter prediction information; and if the diameter prediction information does not match the diameter mode, the high-pressure jet grouting pile diameter output module adjusts an operation parameter of the high-pressure jet grouting pile diameter prediction model, perform prediction again until the diameter prediction information matches the diameter mode, and outputs the diameter prediction information. The system and the method adopt bidirectional recurrent prediction, so that training efficiency is improved to a great extent, the input data of the prediction model is fed back and corrected, change of actual data of the jet grouting pile is accurately reflected with time, effectiveness of model construction is effectively reduced in a high-pressure jet grouting process, suggestions to improve a current high-pressure jet grouting pile design are conveniently put forward based on analysis and prediction results, and potential risks in engineering practice are reduced.

Specific examples are used herein to explain the principles and implementations of the present disclosure. The foregoing description of embodiments is merely intended to help understand the method of the present disclosure and its core ideas; and besides, various modifications may be made by a person of ordinary skill in the art to specific embodiments and the scope of application in accordance with the ideas of the present disclosure. In conclusion, the content of the present specification shall not be construed as limitations to the present disclosure.

1. A real-time dynamic prediction system of a three-dimensional shape of a high-pressure jet grouting pile, comprising a model construction module, a model training module, a prediction module, and a high-pressure jet grouting pile diameter output module, wherein the model construction module is connected with the model training module, the model training module is connected with the prediction module, and the prediction module is connected with the high-pressure jet grouting pile diameter output module;
the model construction module is configured to construct a high-pressure jet grouting pile diameter prediction model based on a bidirectional recurrent neural network (BRNN) and a gated recurrent unit (GRU);
the model training module is configured to: obtain a training data set, and train the high-pressure jet grouting pile diameter prediction model based on the training data set;
the prediction module is configured to perform prediction based on the trained high-pressure jet grouting pile diameter prediction model, to obtain diameter prediction information in a construction process of a construction project; and
the high-pressure jet grouting pile diameter output module is configured to: determine whether the obtained diameter prediction information matches a diameter mode; if the obtained diameter prediction information does not match the diameter mode, adjust an operation parameter of the high-pressure jet grouting pile diameter prediction model and perform prediction again; and if the obtained diameter prediction information matches the diameter mode, output the diameter prediction information.

2. A real-time dynamic prediction method of a three-dimensional shape of a high-pressure jet grouting pile, comprising:
step 1: obtaining a training data set;
step 2: constructing, by a model construction module, a high-pressure jet grouting pile diameter prediction model based on a bidirectional recurrent neural network (BRNN) and a gated recurrent unit (GRU);
step 3: training, by a model training module, the high-pressure jet grouting pile diameter prediction model based on the training data set;
step 4: performing, by a prediction module, prediction based on the trained high-pressure jet grouting pile diameter prediction model, to obtain diameter prediction information in a construction process of a construction project; and
step 5: determining, by a high-pressure jet grouting pile diameter output module, whether the diameter prediction information matches a diameter mode; if the diameter prediction information matches the diameter mode, outputting the diameter prediction information; and if the diameter prediction information does not match the diameter mode, adjusting an operation parameter of the high-pressure jet grouting pile diameter prediction model, and repeating prediction until the diameter prediction information matches the diameter mode, and outputting the diameter prediction information.

3. The real-time dynamic prediction method of a three-dimensional shape of a high-pressure jet grouting pile according to claim 2, wherein in the step 1, the obtaining a training data set specifically comprises:
obtaining parameters of a soil layer based on relevant soil data collected through site survey; obtaining a jetting parameter and a diameter of the high-pressure jet grouting pile based on a high-pressure jet grouting pile test, namely, parameters of a pile test; and constructing the training data set based on the parameters of the soil layer and the parameters of the pile test.

4. The real-time dynamic prediction method of a three-dimensional shape of a high-pressure jet grouting pile according to claim 3, wherein in the step 2, the constructing, by a model construction module, the high-pressure jet grouting pile diameter prediction model based on a BRNN and a GRU specifically comprises:
constructing, by the model construction module, a BRNN and GRU fusion model based on the BRNN and the GRU, namely, the high-pressure jet grouting pile diameter prediction model, wherein the BRNN and GRU fusion model is configured to connect two opposite hidden layers to a same output layer, and the output layer simultaneously receives information forward and backward based on generative deep learning.

5. The real-time dynamic prediction method of a three-dimensional shape of a high-pressure jet grouting pile according to claim 4, wherein in the step 3, the training, by the model training module, the high-pressure jet grouting pile diameter prediction model based on the training data set specifically comprises:
step 301: obtaining, by the model training module, the training data set, and screening an effective data parameter from the parameters of the soil layer and the parameters of the pile test, to enable the BRNN in the high-pressure jet grouting pile diameter prediction model to comprise 300 hidden layers;
step 302: setting an input variable, comprising a jetting parameter, increment time, a soil depth, and porosity, wherein the jetting parameter comprises a revolution Rot per lifting step, a flow rate Q, a number N of nozzles, a diameter d of the nozzle, injection time Dt per lifting step, a mean rotational speed w, an injected grout volume Vj′, and a lifting speed v, and an output is a diameter of a column with a specific depth, wherein for the parameters of the soil layer, all diameter values collected from first six columns are arranged as a soil layer training vector sequence, and for the parameters of the pile test, all diameter values collected from last six columns are arranged as a test training vector sequence;
step 303: inputting the soil layer training vector sequence and the test training vector sequence into a high-pressure jet grouting pile diameter prediction model at corresponding time, and training the high-pressure jet grouting pile diameter prediction model, wherein the BRNN and the GRU in the high-pressure jet grouting pile diameter prediction model are trained for 300 epochs; and
step 304: in the training process, if there is an error between an output training result and an output of a preset labeled structure, transmitting the error to a recurrent neural network of the high-pressure jet grouting pile diameter prediction model step by step through a backward algorithm, automatically adjusting, by the high-pressure jet grouting pile diameter prediction model, weight parameters of each neuron, and stop training after a success rate of the training result reaches a preset threshold, to complete the training of the high-pressure jet grouting pile diameter prediction model.
